(19) United States
(12) Patent Application Publication
(10) Pub. No.: US 2024/0243147 A1
(43) Pub. Date: Jul. 18, 2024

(54) IMAGE SENSORS INCLUDING COLOR ROUTING META-STRUCTURE CONFIGURED TO CORRESPOND TO OBLIQUE INCIDENT LIGHT AND ELECTRONIC DEVICES INCLUDING IMAGE SENSORS

(71) Applicant: SAMSUNG ELECTRONICS CO., LTD., Suwon-si (KR)

(72) Inventors: Sungmo AHN, Suwon-si (KR); Sangeun Mun, Suwon-si (KR); Hyunsung Park, Suwon-si (KR); Sookyoung Roh, Suwon-si (KR); Seokho Yun, Suwon-si (KR); Choonlae Cho, Suwon-si (KR)

(73) Assignee: SAMSUNG ELECTRONICS CO., LTD., Suwon-si (KR)

(21) Appl. No.: 18/414,149

(22) Filed: Jan. 16, 2024

(30) Foreign Application Priority Data
Jan. 16, 2023 (KR) 10-2023-0006310

(51) Int. Cl. H01L 27/146; G02B 1/00

(52) U.S. Cl. CPC H01L 27/14625; G02B 1/002; H01L 27/14645

(57) ABSTRACT

An image sensor includes a plurality of pixels, where each of the plurality of pixels includes a photoelectric conversion layer and a color routing meta-structure layer provided on the photoelectric conversion layer, where a first center line passing through a center of a lower surface and a center of an upper surface of a first color routing meta-structure layer of a first pixel among the plurality of pixels is inclined with respect to a second center line passing through a center of a lower surface and a center of an upper surface of a second color routing meta-structure layer of a second pixel among the plurality of pixels and where at least one of the first center line and the second center line is inclined with respect to an optical axis of the image sensor.

### CROSS-REFERENCE TO RELATED APPLICATION

This application is based on and claims priority under 35 U.S.C. § 119 to Korean Patent Application No. 10-2023-0006310, filed on Jan. 16, 2023, in the Korean Intellectual Property Office, the disclosure of which is incorporated by reference herein in its entirety.

### BACKGROUND

### 1. Field

The disclosure relates to image sensors utilizing a meta-structure including meta-patterns, and more particularly, to image sensors including a color routing meta-structure configured to correspond to oblique incident light and electronic devices including the image sensors.

### 2. Description of the Related Art

Meta-optics refers to the field of optical technology that, by using nanostructures with a scale less than a wavelength of light, may be capable of realizing new optical characteristics that may not be achieved with existing materials.

An image sensor may be a semiconductor optical element that receives light from an image formed by a lens and converts it into an electrical signal.

Each pixel of an image sensor may include a microlens and a color filter. As pixels are gradually manufactured in ultra-fine sizes according to the demand for high-resolution cameras, the size of microlenses and color filters of the pixels has been gradually reduced, and thus, light efficiency may be reduced.

### SUMMARY

Provided are meta-optical devices capable of preventing a decrease in light efficiency according to oblique incident light.

Further provided are image sensors including the meta-optical devices.

Further still provided are electronic devices including the image sensors.

Additional aspects will be set forth in part in the description which follows and, in part, will be apparent from the description, or may be learned by practice of example embodiments.

According to an aspect of the disclosure, an image sensor may include a plurality of pixels, where each of the plurality of pixels may include a photoelectric conversion layer and a color routing meta-structure layer provided on the photoelectric conversion layer, where a first center line passing through a center of a lower surface and a center of an upper surface of a first color routing meta-structure layer of a first pixel among the plurality of pixels may be inclined with respect to a second center line passing through a center of a lower surface and a center of an upper surface of a second color routing meta-structure layer of a second pixel among the plurality of pixels and where at least one of the first center line and the second center line may be inclined with respect to an optical axis of the image sensor.

Each of the plurality of pixels may include an R pixel, a G pixel, and a B pixel and the photoelectric conversion layer may include four photoelectric conversion elements arranged in a 2×2 array.

The first pixel and the second pixel may be provided at locations away from a center of the image sensor.

One of the first pixel or the second pixel may be provided at a center of the image sensor.

Center lines of color routing meta-structure layers corresponding to the plurality of pixels may be inclined differently from each other.

Each of the first color routing meta-structure layer and the second color routing meta-structure layer may include a plurality of meta-structures and where each of the plurality of meta-structures may be symmetric with respect to a center of a corresponding pixel or a reference line passing through the center of the corresponding pixel.

The color routing meta-structure layer may include a plurality of sub-color routing meta-structure layers sequentially provided on the photoelectric conversion layer.

The plurality of sub-color routing meta-structure layers may be shifted toward the optical axis.

The plurality of sub-color routing meta-structure layers may be provided in a layer structure in which a shift increases from a lower layer of the plurality of sub-color routing meta-structure layers to an upper layer of the plurality of sub-color routing meta-structure layers.

A first size of a first meta-structure of the first color routing meta-structure layer may be different from a second size of a second meta-structure of the second color routing meta-structure layer.

The first size and the second size may increase based on to a chief ray angle (CRA) of light incident on the first pixel and the second pixel respectively.

The first size and the second size may decrease based on to a CRA of light incident on the first pixel and the second pixel respectively.

At least one of the first meta-structure and the second meta-structure may include a plurality of different sub-meta-structures.

The image sensor may include spacer between the photoelectric conversion layer and the color routing meta-structure layer.

According to an aspect of the disclosure, a meta-optical device may include a plurality of regions respectively corresponding to a plurality of pixels of an image sensor, where the plurality of regions may include a first region including a first color routing meta-structure layer and a second region including a second color routing meta-structure layer, and where a first center line passing through a center of a lower surface and a center of an upper surface of the first color routing meta-structure layer may be inclined with respect to a second center line passing through a center of a lower surface and a center of an upper surface of the second color routing meta-structure layer.

A first CRA of light incident on the first region and a second CRA of light incident on the second region may be different.

The first color routing meta-structure layer and the second color routing meta-structure layer may include layer structures including at least one layer shifted towards a center of the image sensor.

The first color routing meta-structure layer may include a first layer, a second layer, a third layer, a fourth layer, and a fifth layer stacked in sequence and including color routing characteristics, and a first shift of the first layer toward the center of the image sensor may be less than at least a second shift of the fifth layer toward the center of the image sensor.

The first color routing meta-structure layer may include a first meta-structure, where the second color routing meta-structure layer may include a second meta-structure, where the first meta-structure and the second meta-structure may have a same shape, and where the first meta-structure and the second meta-structure may have different sizes.

According to an aspect of the disclosure, an electronic device may include an image sensor including a plurality of pixels, where each of the plurality of pixels may include a photoelectric conversion layer and a color routing meta-structure layer provided at a location facing the photoelectric conversion layer, where a first center line passing through a center of a lower surface and a center of an upper surface of a first color routing meta-structure layer of a first pixel of the plurality of pixels may be inclined with respect to a second center line passing through a center of a lower surface and a center of an upper surface of a second color routing meta-structure of a second pixel of the plurality of pixels and where at least one of the first center line and the second center line may be inclined with respect to an optical axis of the image sensor.

### BRIEF DESCRIPTION OF THE DRAWINGS

The above and/or other aspects, features, and advantages of certain example embodiments of the disclosure will be more apparent from the following description taken in conjunction with the accompanying drawings, in which:

FIG. 1 is a cross-sectional view showing incident light having different chief ray angles (CRAs) on an image sensor according to an example embodiment;

FIG. 2 is a plan view illustrating a pixel array of the image sensor of FIG. 1 according to an example embodiment;

FIG. 3 is a diagram of a unit pixel of FIG. 2 according to an example embodiment;

FIG. 4 is a cross-sectional view taken along line 4-4′ of FIG. 2 according to an example embodiment;

FIG. 5 is a cross-sectional view illustrating a pixel located at the center of the pixel array of FIGS. 2 and 4 according to an example embodiment;

FIG. 6 is a cross-sectional view illustrating a pixel located at an edge of a first side of the pixel array of FIGS. 2 and 4 according to an example embodiment;

FIG. 7 is a cross-sectional view illustrating a pixel located at an edge of a second side of the pixel array of FIGS. 2 and 4 according to an example embodiment;

FIGS. 8A and 8B are graphs showing simulation results to confirm color separation efficiency according to meta-structures of pixels located at edges of an image sensor according to an example embodiment;

FIG. 9 is a cross-sectional view illustrating a shifting degree of a meta-structure of a pixel deviating from the center of an image sensor in an image sensor according to an example embodiment;

FIG. 10 is a plan view of a first layer of the meta-structure layer shown in FIGS. 5 to 7 according to an example embodiment;

FIG. 11 is a plan view of a second layer of the meta-structure layer shown in FIGS. 5 to 7 according to an example embodiment;

FIG. 12 is a plan view of a third layer of the meta-structure layer shown in FIGS. 5 to 7 according to an example embodiment;

FIG. 13 is a plan view of a fourth layer of the meta-structure layer shown in FIGS. 5 to 7 according to an example embodiment;

FIG. 14 is a plan view of a fifth layer of the meta-structure layer shown in FIGS. 5 to 7 according to an example embodiment;

FIG. 15 is a diagram illustrating a case in which a size of a meta-structure of a pixel deviated from the center of an image sensor is increased compared to a size of a meta-structure of a pixel located in the center of an image sensor according to an example embodiment;

FIG. 16 is a diagram illustrating a case in which a size of a meta-structure of a pixel deviated from the center of an image sensor is reduced compared to a size of a meta-structure of a pixel located in the center of an image sensor according to an example embodiment;

FIG. 17 is a diagram illustrating an electronic device according to an example embodiment; and

FIG. 18 is a diagram showing a schematic configuration of a camera module included in the electronic device of FIG. 17 according to an example embodiment.

### DETAILED DESCRIPTION

Reference will now be made in detail to embodiments, examples of which are illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, an image sensor including a color routing meta-structure (meta-optical device) configured to correspond to oblique incident light and an electronic device including the image sensor according to an example embodiment will be described in detail with reference to the accompanying drawings.

The meta-optical device will be described together with the image sensor. In the following description, thicknesses of layers or regions in drawings may be somewhat exaggerated for clarity of the specification. In addition, the embodiments of the disclosure are capable of various modifications and may be embodied in many different forms. In addition, when an element or layer is referred to as being “on” or “above” another element or layer, the element or layer may be directly on another element or layer or intervening elements or layers. In the description below, like reference numerals in each drawing denote like members.

Recently, research results on a high-efficiency color routing meta-structure applicable to an image sensor based on meta-optics have been reported, and incident light is separated by color (i.e., by wavelength), while passing through the color routing meta-structure and the separated light is collected by wavelength.

The color routing meta-structure may refer to a nanostructure with a scale less than a wavelength, and also may have a structural form not only on a plane on which image sensor pixels are disposed but also in a direction in which light travels (in a depth direction). As a result, the color routing meta-structure may be a three-dimensional nanostructure.

The design of such a color routing meta-structure is usually performed by repeatedly optimizing the structure for an objective function such as light efficiency. For example, in the color routing meta-structure for an image sensor, an objective function is set and a meta-structure is optimized such that light efficiency for a wavelength corresponding to each pixel is increased.

However, a chief ray angle (CRA) of light incident on a center of the image sensor and a CRA of light incident on an off-center location (e.g., an edge) may be different. Accordingly, light efficiency (e.g., a color separation efficiency) of a pixel in a center of the image sensor and a pixel in an off-center area of the image sensor may be different.

Due to the difference in CRA, color separation efficiency of pixels located in the off-center areas of the image sensor may be lower than color separation efficiency of pixels located in the center of the image sensor. Therefore, in a process of optimizing a meta-structure, an objective function may be set such that light efficiency degradation of pixels located in the off-center areas of the image sensor may be improved.

Depending on the setting of the objective function, a color routing meta-structure of an image sensor may be designed in various ways.

Hereinafter, a color routing meta-structure designed to improve light efficiency degradation of pixels located in the off-center areas of an image sensor will be described in more detail with reference to drawings.

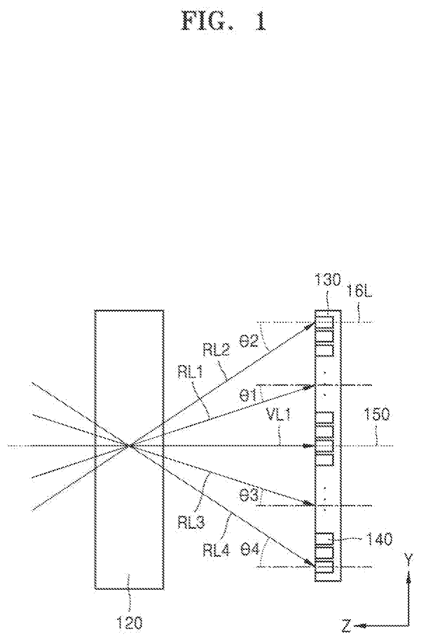

FIG. 1 is a cross-sectional view showing incident light having different chief ray angles (CRAs) on an image sensor according to an example embodiment. FIG. 1 shows an example in which light having different CRAs is incident to an image sensor including a color routing meta-structure according to an example embodiment.

In FIG. 1, a lens system 120 collects light incident from an object (subject) to the image sensor 130. Light incident from an object may include light reflected from the object. The lens system 120 may include a single lens, but may also include a plurality of lenses having different focal points. The lens system 120 may further include an aperture or other member in addition to the lens.

Referring to FIG. 1, among lights VL1, RL1, RL2, RL3, and RL4 incident on an image sensor 130 through the lens system 120, the light VL1 perpendicularly incident to a center of the image sensor 130 is light parallel to an optical axis 150 passing through the center of the image sensor 130 and has a CRA of 0°. The optical axis 150 may be parallel to a direction (e.g., a Z-axis direction) perpendicular to a light incident surface of the image sensor 130. The first light RL1 is light inclined at a first inclination angle with respect to the optical axis 150 and has a CRA of a first angle θ1. The first inclination angle may be equal to the first angle θ1. The second light RL2 is light inclined at a second inclination angle with respect to the optical axis 150 and has a CRA of a second angle θ2. The second inclination angle may be equal to the second angle θ2. The second angle θ2 may be greater than the first angle θ1.

In one example, the second light RL2 may be oblique light incident on a unit pixel 140 located at a first edge (e.g., an outermost edge) of a first side (e.g., Y-axis+ direction) of the image sensor 130, and the first light RL1 may be oblique light incident on the unit pixel 140 located at any position between the first edge and the center of the image sensor 130.

The third light RL3 is oblique light incident on the image sensor 130 with a third inclination angle with respect to the optical axis 150 and has a CRA of a third angle θ3. The third inclination angle may be the same as the third angle θ3. The size of the third angle θ3 may be the same as or different from the first angle θ1. The third light RL3 may be symmetrical with the first light RL1 with the optical axis 150 as a center.

The fourth light RL4 is oblique light incident on the image sensor 130 with a fourth inclination angle with respect to the optical axis 150, and has a CRA of a fourth angle θ4. The fourth inclination angle may be the same as the fourth angle θ4. The size of the fourth angle θ4 may be the same as or different from the second angle θ2.

The fourth light RL4 may be oblique light incident on the unit pixel 140 located at a second edge (e.g., an outermost edge) of a second side (e.g., the Y-axis − direction) of the image sensor 130, and the third light RL3 may be oblique light incident on the unit pixel 140 located at any position between the second edge and the center of the image sensor 130.

In FIG. 1, 16L represents a normal line perpendicular to a light incident surface of the image sensor 130. The first to fourth angles θ1, θ2, θ3, and θ4 may be measured based on the normal line 16L.

In one example, the second angle θ2 and the fourth angle θ4 may be about 45°, but are not limited thereto. For example, the second angle θ2 may be 40°, 35°, or 25° or less, and the fourth angle θ4 may be the same.

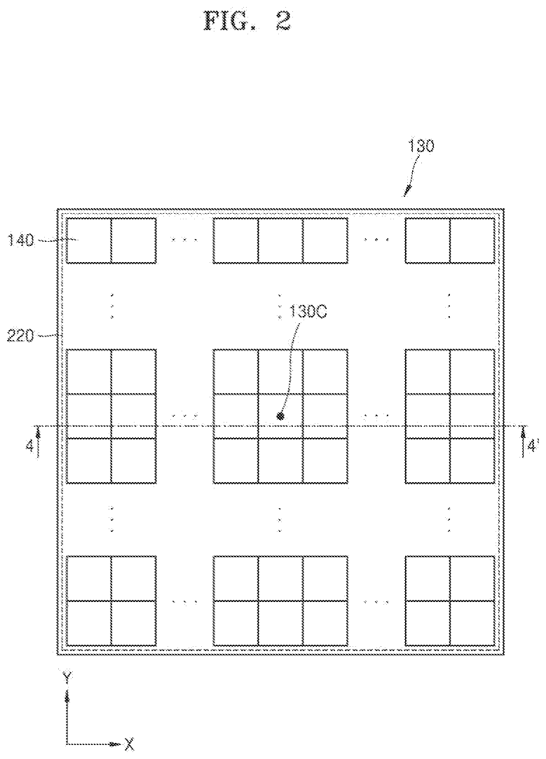

FIG. 2 is a plan view illustrating a pixel array 220 of the image sensor 130 of FIG. 1 according to an example embodiment. The center 130C of the pixel array 220 is depicted. The pixel array 220 may correspond to the light incident surface of the image sensor 130. The center 130C of the pixel array 220 may correspond to the center of the image sensor 130 when viewing the light incident surface from the front. The pixel array 220 includes a plurality of unit pixels 140 aligned in first and second directions (e.g., the X direction and the Y-direction). The first and second directions may be perpendicular to each other. In one example, the first direction may be parallel to an X-axis. In one example, the second direction may be parallel to a Y-axis. The first direction may be expressed as a horizontal direction and the second direction may be expressed as a vertical direction, or vice versa depending on the perspective.

FIG. 3 is a diagram of a unit pixel of FIG. 2 according to an example embodiment. In one example, as shown in FIG. 3, the unit pixel 140 may include four pixels PX1 to PX4 disposed in 2 rows x 2 columns (2*2) (e.g., a 2×2 array). However, the unit pixel 140 is not limited thereto, and may include more pixels. Each of the four pixels PX1 to PX4 may also be represented by subpixels.

In one example, the first to fourth pixels PX1 to PX4 may be pixels aligned to form a bayer pattern, but are not limited to the form of a bayer pattern. In one example, the first pixel PX1 may be an R-pixel that receives red light R, the second and third pixels PX2 and PX3 may be G-pixels that receive green light G, and the fourth pixel PX4 may be a B-pixel that receives blue light B.

As another example, at least one of the first to fourth pixels PX1 to PX4 may be a pixel that receives infrared light IR, or a pixel that receives white light W. As another example, the first to fourth pixels PX1 to PX4 of the unit pixel 140 may be used as pixels for receiving cyan light, magenta light, and yellow light.

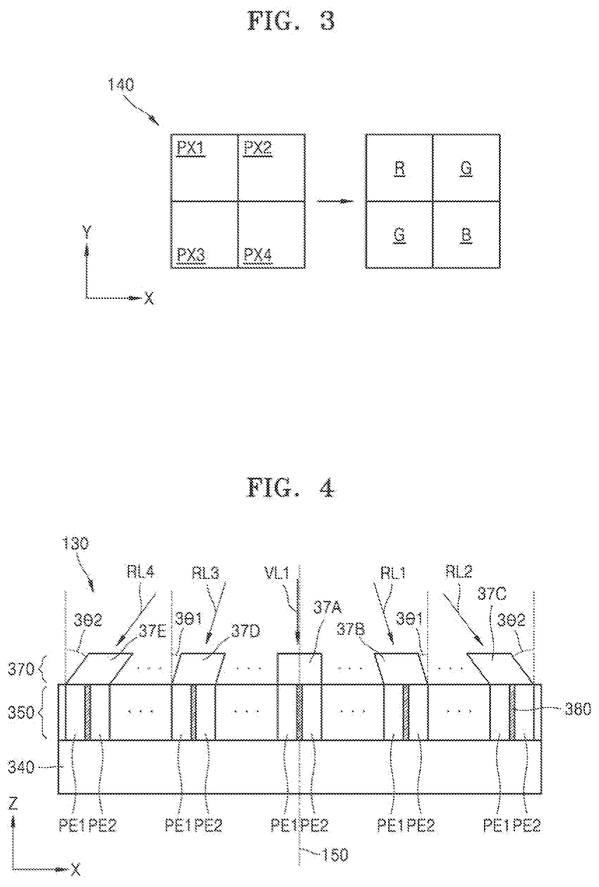

FIG. 4 is a cross-sectional view taken along line 4-4′ of FIG. 2 according to an example embodiment.

Referring to FIG. 4, the image sensor 130 may include a substrate 340, a photoelectric conversion layer 350 on the substrate 340, and a color routing meta-structure layer 370 on the photoelectric conversion layer 350. The substrate 340 may be a substrate including a circuit or circuit unit for driving and controlling a photoelectric conversion element included in the photoelectric conversion layer 350 and for outputting an electrical signal related to an image. The circuit may include a readout integrated circuit (ROIC).

The photoelectric conversion layer 350 may include a plurality of first and second photoelectric conversion elements PE1 and PE2 aligned on the substrate 340. The plurality of first photoelectric conversion elements PE1 and the plurality of second photoelectric conversion elements PE2 may be repeated in the first direction (e.g., X-axis direction).

The first and second photoelectric conversion elements EP1 and EP2 may be photoelectric conversion elements belonging to two selected pixels among the first to fourth pixels PX1 to PX4 of FIG. 3. For example, depending on a location of cutting the image sensor 130 of FIG. 2, the first and second photoelectric conversion elements PE1 and PE2 may be photoelectric conversion elements belonging to the first pixel PX1 and the second pixel PX2, or may be photoelectric conversion elements belonging to the third pixel PX3 and the fourth pixel PX4, respectively.

A barrier wall 380 may be present to prevent light interference and leakage of light current between the first and second photoelectric conversion elements PE1 and PE2. As an example, the barrier wall 380 may include a structure (e.g., deep trench isolation (p-DTI)) in which a trench is partially formed between the first and second photoelectric conversion elements PE1 and PE2, or a structure (f-DTI) in which the trench is entirely formed. In one example, the first and second photoelectric conversion elements PE1 and PE2 may be photo diodes or include photo diodes, but are not limited thereto.

The color routing meta-structure layer 370 includes a plurality of sub-color routing meta-structure layers 37A to 37E aligned on the photoelectric conversion layer 350. The plurality of sub-color routing meta-structure layers 37A to 37E may be provided in a one-to-one correspondence with the unit pixel 140. Therefore, each of the sub-color routing meta-structure layers 37A to 37E may be located on each unit pixel 140.

The plurality of sub-color routing meta-structure layers 37A to 37E may have an inclined structure toward the center 130C of the image sensor 130. The degree of inclination of each of the sub-color routing meta-structure layers 37A to 37E may be measured by an angle between the optical axis 150 and a straight line passing through the center of a lower surface and the center of an upper surface of each of the sub-color routing meta-structure layers 37A to 37E. The degree of inclination may be expressed as an inclination angle of each of the sub-color routing meta-structure layers 37A to 37E with respect to the optical axis 150.

The sub-color routing meta-structure layer 37A provided at the center 130C of the image sensor 130 is parallel to the optical axis 150 and does not have a slope with respect to the optical axis 150. In other words, the inclination angle of the sub-color routing meta-structure layer 37A at the center 130C of the image sensor 130 is 0°. The degree of inclination of the sub-color routing meta-structure layers 37B-37E with respect to the optical axis 150 at a location away from the center 130c of the image sensor 130 may be different depending on locations of the sub-color routing meta-structure layers 37B to 37E. For example, the degree of inclination (i.e., inclination angle 3θ2) of the sub-color routing meta-structure layers 37C and 37E, to which second and fourth light RL2 and RL4 with the largest CRA are incident and which are located at edges of the image sensor 130, may be the largest, and as the closer to the center 130C of the image sensor 130, the degree of inclination may decrease. The sub-color routing meta-structure layers 37B and 37D located at the same or substantially the same distance from the center 130C of the image sensor 130 may be inclined to the same inclination angle 3θ1. That is, the inclination angle 3θ1 may be less than the inclination angle 3θ2.

In one example, an intermediate layer may be provided between the photoelectric conversion layer 350 and the color routing meta-structure layer 370. The intermediate layer may be a material layer that is transparent to incident light and may provide a spatial distance through which light separated by the color routing meta-structure layer 370 reaches the photoelectric conversion layer 350. The intermediate layer may be expressed as a spacer. In one example, the intermediate layer may be a silicon oxide layer or include such a material layer, but is not limited thereto.

The substrate 340, the photoelectric conversion layer 350, and the color routing meta-structure layer 370 may be sequentially stacked, but other material layers may further be formed between the layers in addition to the intermediate layer.

In one example, each of the sub-color routing meta-structure layers 37A to 37E may be configured to have a multi-layer structure.

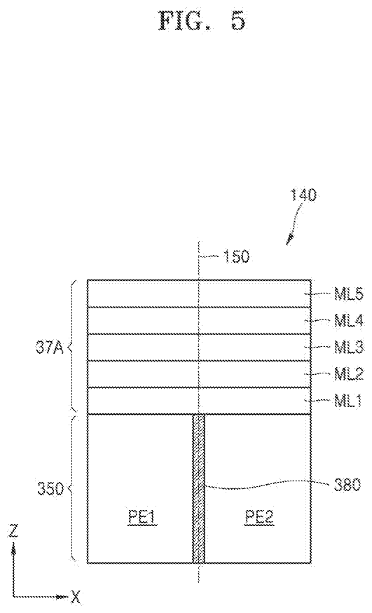

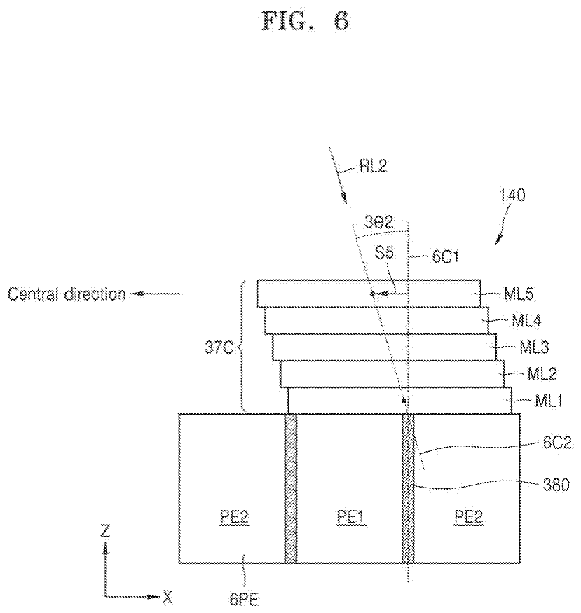

FIG. 5 is a cross-sectional view illustrating a pixel located at the center of the pixel array of FIGS. 2 and 4 according to an example embodiment. FIG. 6 is a cross-sectional view illustrating a pixel located at an edge of a first side of the pixel array of FIGS. 2 and 4 according to an example embodiment. FIG. 7 is a cross-sectional view illustrating a pixel located at an edge of a second side of the pixel array of FIGS. 2 and 4 according to an example embodiment. FIGS. 5 to 7 show example structures of the sub-color routing meta-structure layers 37B to 37E.

FIG. 5 shows the sub-color routing meta-structure layer 37A located at the center 130C of the image sensor 130. FIG. 6 shows the sub-color routing meta-structure layer 37C located at an edge of a first side of the image sensor 130. FIG. 7 shows the sub-color routing meta-structure layer 37E located at an edge of a second side of the image sensor 130. The second side is on an opposite side to the first side, and the first and second sides may face each other with the center 130C of the image sensor 130 therebetween.

Referring to FIG. 5, the sub-color routing meta-structure layer 37A located at the center 130C of the image sensor 130 (i.e., on the optical axis 150) may include first to fifth layers ML1 to ML5 sequentially stacked on the first and second photoelectric conversion elements PE1 and PE2. Each of the layers ML1 to ML5 may include a plurality of meta patterns. Each of the plurality of meta-patterns may have a dimension (e.g., height, diameter, pitch, etc.) less than a wavelength of incident light. The plurality of meta patterns in each of the layers ML1 to ML5 may be distributed to form a meta-structure for color routing. That is, each of the layers ML1 to ML5 may be a color routing meta-structure layer. A color routing operation may be different for each of the layers ML1 to ML5. Therefore, a meta-structure formed in each of the layers ML1 to ML5 may be different for each layer. Thicknesses of the respective layers ML1 to ML5 may be the same or substantially the same, and may be different from each other. For example, one layer or some of the first to fifth layers ML1 to ML5 may have a thickness different from the other layers. In one example, sizes (e.g., widths) of the first to fifth layers ML1 to ML5 in a first direction (X-axis direction) may be the same or substantially the same. The first layer ML1 may be provided to cover an entire upper surface (e.g., an entire entrance through which light is incident) of the photoelectric conversion layer 350 of the unit pixel 140.

The sub-color routing meta-structure layer 37A may include 5 layers, more than 5 layers, or less than 5 layers.

As shown in FIGS. 6 and 7, the sub-color routing meta-structure layers 37C and 37E located at the edges of the image sensor 130 also may have a layer structure including the first to fifth layers ML1 to ML5 similar to the sub-color routing meta-structure layer 37A located at the center of the image sensor 130C. In one example, the number of layers of the plurality of sub-color routing meta-structure layers 37A to 37E included in the color routing meta-structure layer 370 may be different from each other. For example, the number of layers included in the sub-color routing meta-structure layer 37A located at the center 130C of the image sensor 130 and the number of layers included in the sub-color routing meta-structure layers 37C and 37E located at the edge may be different from each other.

As described with reference to FIG. 4, the color routing meta-structure layer 370 is provided to correspond to incident light having different CRAs. Therefore, even though the number of layers of each layer of the sub-color routing meta-structure layers 37A to 37E is the same, the layer structure of the sub-color routing meta-structure layer 37A located at the center 130C of the image sensor 130 may be different from the layer structure of the sub-color routing meta-structure layers 37B to 37E located away from the center 130C of the image sensor 130. In addition, layer structures including the first to fifth layers ML1 to ML5 between the sub-color routing meta-structure layers 37B to 37E that are away from the center 130C may be different from each other.

For example, as shown in FIG. 5, in the case of the sub-color routing meta-structure layer 37A located at the center 130C of the image sensor 130, the centers of the first to fifth layers ML1 to ML5 are located on the same vertical line (e.g., optical axis 150).

On the other hand, as shown in FIG. 6, in the case of the sub-color routing meta-structure layer 37C located at the edge of the first side of the image sensor 130 (e.g., the + direction of the X-axis in FIG. 4), the first to fifth layers ML1 to ML5 are shifted toward the center 130C of the image sensor 130 based on a vertical line 6C1 passing through the center 130C of the unit pixel 140. The degree of shift of each of the first to fifth layers ML1 to ML5 in the horizontal direction perpendicular to the vertical line 6C1 (e.g., the − direction of the X axis) from the vertical line 6C1 increases from the first layer ML1 to the fifth layer ML5. In one example, a distance at which the center (i.e., the black dots depicted in FIG. 6) of the first layer ML1 is shifted from the vertical line 6C1 (i.e., a horizontal distance between the center of the first layer ML1 and the vertical line 6C1) may be less than a distance at which the center of the second layer ML2 is shifted from the vertical line 6C1 (i.e., a horizontal distance between the center of the second layer ML2 and the vertical line 6C1), which may be less than a distance at which a center of the third layer ML3 is shifted from the vertical line 6C1 (i.e., a horizontal distance between the center of the third layer ML3 and the vertical line 6C1), which may be less than a distance at which a center of the fourth layer ML4 is shifted from the vertical line 6C1 (i.e., a horizontal distance between the center of the fourth layer ML4 and the vertical line 6C1), which may be less than a distance S5 at which a center of the fifth layer ML5 is shifted from the vertical line 6C1 (i.e., a horizontal distance between the center of the fifth layer ML5 and the vertical line 6C1).

In this way, because the center of each of the first to fifth layers ML1 to ML5 is shifted in the horizontal direction from the vertical line 6C1, and the degree of shift increases from the lower layer to the upper layer, a straight line connecting the centers of the first to fifth layers ML1 to ML5 (i.e., a center line 6C2) may be inclined at an inclination angle 3θ2 with respect to the vertical line 6C1.

In the above example, it has been described that the shift distance between each of the first to fifth layers ML1 to ML5 differs by the same, predetermined shift distance, but the shift difference between each of the first to fifth layers ML1 to ML5 may be greater or less than the predetermined shift distance. That is, as shown in FIG. 6, the shift distance between the center of layer ML1 and the line 6C1 may be a value of x, the shift distance between the center of layer ML2 and the line 6C1 may be a value of 2×, the shift distance between the center of layer ML3 and the line 6C1 may be a value of 3×, etc. In some embodiments, the center of the layers ML1-ML5 may be shifted at distances that vary from a structured multiplier.

In one example, the degree of shift of the uppermost layer ML5 may be limited to a range in which the deterioration of light efficiency due to CRA is minimized or prevented without interfering with light incident to adjacent pixels 6PE.

FIG. 7 shows shifts of the first to fifth layers ML1 to ML5 of the sub-color routing meta-structure layer 37E at the edge of the second side of the image sensor 130. The edge of the second side is opposite to the edge of the first side, except that the shift direction is opposite, the shift of the first to fifth layers ML1 to ML5 of the sub-color routing meta-structure layer 37E located at the edge of the second side may be the same as the shift of the first to fifth layers ML1 to ML5 of the sub-color routing meta-structure layer 37C located at the edge of the first side.

Accordingly, as shown in FIG. 7, the centers of the first to fifth layers ML1 to ML5 of the sub-color routing meta-structure layer 37E are horizontally shifted toward the center 130C of the image sensor 130 from a vertical line 7C1 passing through the center of the unit pixel 140, and because the degree of shifting increases vertically (i.e., the degree of shift increases from layer ML1 to layer ML5), a straight line connecting the centers of the first to fifth layers ML1 to ML5 (i.e., a center line 7C2) may be inclined at the inclination angle 3θ2 with respect to the vertical line 7C1. As described with reference to FIG. 4, the inclination angle 3θ2 between the center line 7C2 and the vertical line 7C1 may decrease as the location of the unit pixel 140 approaches the center 130C of the image sensor 130.

In one example, the degree of shift of the uppermost layer ML5 of the sub-color routing meta-structure layer 37E may be limited to a range in which the deterioration of light efficiency due to CRA is minimized or prevented without interfering with light incident to the adjacent pixel 7PE.

In the sub-color routing meta-structure layers 37A to 37E of the color routing meta-structure layer 370, a lower surface of the first layer ML1, which is the lowest layer, may be a lower surface of each of the sub-color routing meta-structure layers 37A to 37E, and an upper surface of the fifth layer M5, which is the uppermost layer, may be an upper surface of each of the sub-color routing meta-structure layers 37A to 37E.

In the case of FIG. 5, the center line passing through the center of the lower surface and the center of the upper surface of the sub-color routing meta-structure layer 37A is parallel to the optical axis 150. However, in the case of FIGS. 6 and 7, the center lines 6C2 and 7C2 passing through the center of the lower surface and the center of the upper surface of each of the sub-color routing meta-structure layers 37C and 37E are not parallel to the optical axis 150 and are inclined with respect to the optical axis 150.

The center lines of the sub-color routing meta-structure layers 37B to 37E of the pixels located away (e.g., spaced apart from) from the center 130C of the image sensor 130 are all inclined with respect to the optical axis 150, although the degrees of inclination are different.

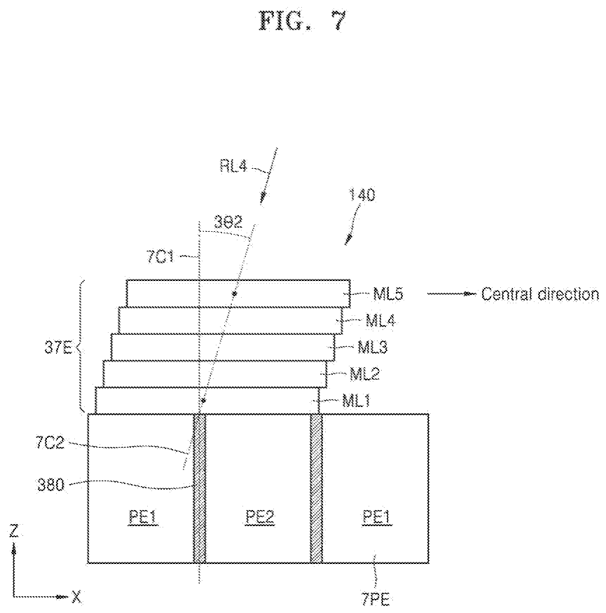

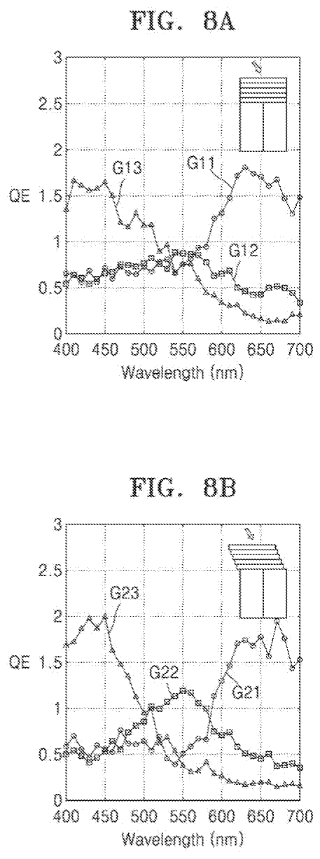

FIGS. 8A and 8B are graphs showing simulation results to confirm color separation efficiency according to meta-structures of pixels located at edges of an image sensor according to an example embodiment. That is, FIG. 8A shows simulation results performed to confirm color separation efficiency characteristics with respect to a first case in which a color routing meta-structure layer of a pixel located away from the center 130C of the image sensor 130 (e.g., a pixel located at an edge of the image sensor 130) is not inclined toward the center 130C of the image sensor 130. FIG. 8B shows a second case in which the color routing meta-structure layer is inclined toward the center 130C of the image sensor 130.

In the simulations, the color routing meta-structure layers in the first and second cases are set to include first to fifth color routing meta-structure layers. In the first case, the first to fifth color routing meta-structure layers are set to have a stacked layer structure like the first to fifth layers ML1 to ML5 shown in FIG. 5. In the second case, the first to fifth color routing meta-structure layers are set to have a stacked layer structure like the first to fifth layers ML1 to ML5 shown in FIG. 6. In the second case, the degree of shift of the first to fifth color routing meta-structure layers was set to increase from the first layer to the fifth layer, and using a shift amount of the first layer as a reference shift amount, the shift amount toward the upper layers was set to increase 2 times, 3 times, and 4 times with respect to the reference shift amount. That is, when the shift amount of the first layer was S1 with respect to a reference line, the shift amount of the second layer was set to be 2S1 with respect to the reference line, and the shift amount of the third layer was set to be 3S1 with respect to the reference line.

In FIGS. 8A and 8B, the horizontal axis represents wavelength, and the vertical axis represents color separation efficiency.

In FIGS. 8A and 8B, first lines G11 and G21 represent separation efficiencies for red light, second lines G12 and G22 represent separation efficiencies for green light, and third lines G13 and G23 represent separation efficiency for blue light.

In FIGS. 8A and 8B, comparing the first lines G11 and G21, red light separation efficiency in the second case is higher than that in the first case. Comparing the second lines G12 and G22, the green light separation efficiency in the second case is higher than that in the first case. Comparing the third lines G13 and G23, the blue light separation efficiency in the second case is higher than that in the first case.

In the simulation, the setting conditions in the first and second cases were the same except for the shift of the color routing meta-structure layer. Therefore, the results shown in FIGS. 8A and 8B depend on whether the color routing meta-structure layer is shifted or not.

As a result, FIGS. 8A and 8B show that, regarding the image sensor according to an embodiment, the color separation efficiency of the corresponding pixel may be increased when a color routing meta-structure layer of a pixel located away from the center of an image sensor is appropriately shifted toward the center of the image sensor within a set range considering the location of the pixel.

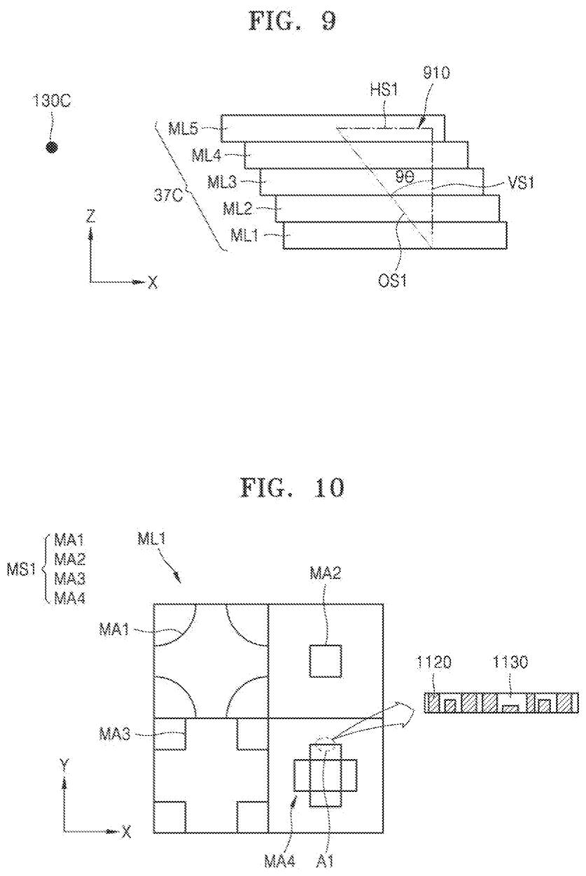

In the image sensor 130 according to an example embodiment, a color routing meta-structure layer of a pixel located at a location away from the center 130C of the image sensor 130 is formed to be shifted toward the center 130C of the image sensor 130, and the degree of shift (shift amount) may be determined within a set range according to the location of the pixel. FIG. 9 shows a method of calculating the degree of shift.

FIG. 9 is a cross-sectional view illustrating a shifting degree of a meta-structure of a pixel deviating from the center of an image sensor in an image sensor according to an example embodiment. In FIG. 9, the method of calculating the degree of shift for the sub-color routing meta-structure layer 37C illustrated in FIG. 6 is explained.

Referring to FIG. 9, a triangle 910 is depicted for explanation in calculating the degree of shift, and is depicted by overlapping with the sub-color routing meta-structure layer 37C.

In the triangle 910, the hypotenuse OS1 may correspond to incident light obliquely incident with respect to a vertical side VS1. An inclination angle 90 of the hypotenuse OS1 with respect to the vertical side VS1 may be an acute angle. In one example, the inclination angle 90 may correspond to a CRA of light incident on the sub-color routing meta-structure layer 37C and may be 45° or less (e.g., 40° or less, 30° or less, or 25° or less), but is not limited thereto.

The vertical side VS1 corresponds to a thickness of the first to fifth layers ML1 to ML5 of the sub-color routing meta-structure layer 37C and may be parallel to the vertical line 6C1 and the optical axis 150 of FIG. 6. A horizontal side HS1 indicates a movement distance of the first to fifth layers ML1 to ML5 of the sub-color routing meta-structure layer 37C according to a length of the vertical side VS1 and/or the inclination angle 90 of the hypotenuse OS1 (i.e., the degree of shift).

The length (shift amount) of the horizontal side HS1, the length of the vertical side VS1, and the inclination angle 9θ of the hypotenuse OS1 satisfy Equation (1) below.

Length of horizontal side (shift amount)=length of vertical side VS1*tan 9θ (1)

The length of the vertical side VS1 corresponds to the thickness of at least one of the first to fifth layers ML1 to ML5. For example, the length of the vertical side VS1 may be the thickness of the first layer ML1, a sum of the thicknesses of the first and second layers ML1 and ML2, a sum of the thicknesses of the first to third layers ML1 to ML3, a sum of the thicknesses of the first to fourth layers ML1 to ML4, or a sum of the thicknesses of the first to fifth layers ML1 to ML5.

When the inclination angle 90 of the hypotenuse OS1 is constant, and if the length of the vertical side VS1 corresponds to the thickness of the first layer ML1 (hereinafter referred to as first thickness), the length of the horizontal side HS1 represents a shift amount of the first layer ML1. When the length of the vertical side VS1 corresponds to the sum of the thickness of the first layer ML1 and the thickness of the second layer ML2 (hereinafter referred to as a second thickness), the length of the horizontal side HS1 represents a shift amount of the second layer ML2.

When the length of the vertical side VS1 corresponds to the sum of the thicknesses of the first to third layers ML1 to ML3 (hereinafter referred to as a third thickness), the length of the horizontal side HS1 represents a shift amount of the third layer ML3.

When the length of the vertical side VS1 corresponds to the sum of the thicknesses of the first to fourth layers ML1 to ML4 (hereinafter referred to as a fourth thickness), the length of the horizontal side HS1 represents a shift amount of the fourth layer ML4.

When the length of the vertical side VS1 corresponds to the sum of the thicknesses of the first to fifth layers ML1 to ML5 (hereinafter referred to as a fifth thickness), the length of the horizontal side HS1 represents a shift amount of the fifth layer ML5.

The second thickness is greater than the first thickness, the third thickness is greater than the second thickness, the fourth thickness is greater than the third thickness, and the fifth thickness is greater than the fourth thickness. Accordingly, the amount of shift increases from the first layer ML1 to the fifth layer ML5.

The first to fifth layers ML1 to ML5 may have the same thickness, but some layers may have different thicknesses from the others. In this case, the length of the horizontal side HS1 may be different from the case when the thicknesses of the first to fifth layers ML1 to ML5 are the same.

When the thicknesses of the first to fifth layers ML1 to ML5 are constant, the length of the horizontal side HS1 may vary according to the inclination angle 9θ of the hypotenuse OS1. Thus, when a layer configuration of the sub-color routing meta-structure layer is constant, the shift amount of each layer of the first to fifth layers ML1 to ML5 of the sub-color routing meta-structure layer may vary according to a CRA. For example, when a CRA is less than the inclination angle 9θ of the hypotenuse OS1, the shift amount of each layer of the first to fifth layers ML1 to ML5 is less than when the CRA is equal to the inclination angle 9θ of the hypotenuse OS1, and when the CRA is greater than the inclination angle 9θ of the hypotenuse OS1, the shift amount of each layer of the first to fifth layers ML1 to ML5 may be increased greater than when the CRA is equal to the inclination angle 9θ of the hypotenuse OS1.

The description of FIG. 9 refers to the sub-color routing meta-structure layer 37C illustrated in FIG. 6, but the description related to the calculation of the degree of shift described above and Equation (1) may be equally applied to the sub-color routing meta-structure layer 37E illustrated in FIG. 7.

The first to fifth layers ML1 to ML5 of the sub-color routing meta-structure layers 37A to 37E of the image sensor 130 according to an embodiment may have different meta-structures from each other. FIGS. 10 to 14 are plan views illustrating examples meta-structures.

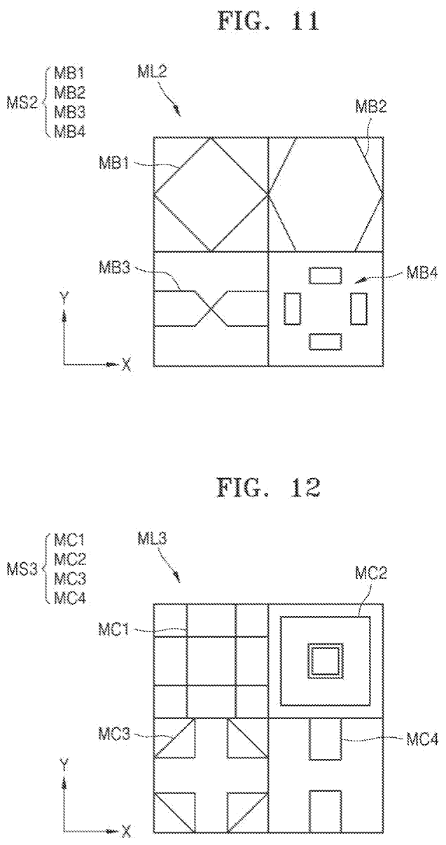

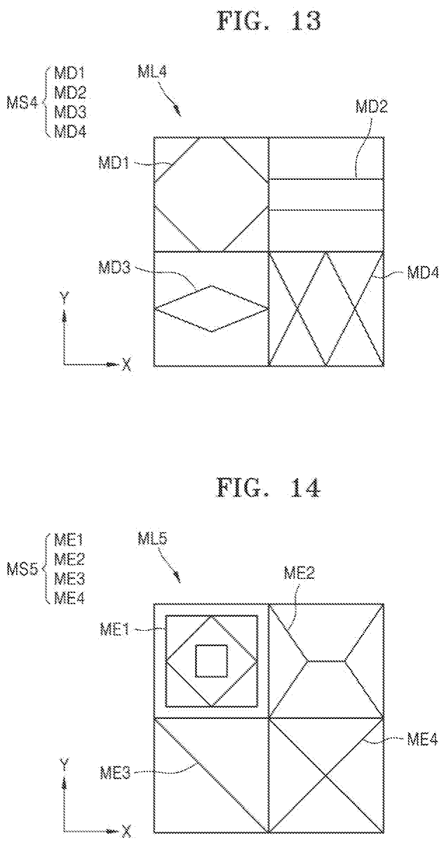

FIG. 10 is a plan view of a first layer of the meta-structure layer shown in FIGS. 5 to 7 according to an example embodiment. FIG. 11 is a plan view of a second layer of the meta-structure layer shown in FIGS. 5 to 7 according to an example embodiment. FIG. 12 is a plan view of a third layer of the meta-structure layer shown in FIGS. 5 to 7 according to an example embodiment. FIG. 13 is a plan view of a fourth layer of the meta-structure layer shown in FIGS. 5 to 7 according to an example embodiment. FIG. 14 is a plan view of a fifth layer of the meta-structure layer shown in FIGS. 5 to 7 according to an example embodiment. That is, FIG. 10 shows a first meta-structure formed on the first layer ML1, FIG. 11 shows a second meta-structure formed on the second layer ML2, FIG. 12 shows a third meta-structure formed on the third layer ML3, FIG. 13 shows a fourth meta-structure formed on the fourth layer ML4, and FIG. 14 shows a fifth meta-structure formed on the fifth layer ML5.

Referring to FIG. 10, the first meta-structure MS1 includes a first sub-meta-structure MA1 corresponding to the first pixel PX1, a second sub-meta-structure MA2 corresponding to the second pixel PX2, a third sub-meta-structure MA3 corresponding to the third pixel PX3, and a fourth sub-meta-structure MA4 corresponding to the fourth pixel PX4 (e.g., pixels PX1-PX4 of FIG. 3), respectively. Each of the first to fourth sub-meta-structures MA1 to MA4 may be formed to be vertically, horizontally, and/or diagonally symmetric with respect to the center of a corresponding pixel or a reference line (e.g., a horizontal or vertical line) passing through the center of the pixel. Each of the first to fourth sub-meta-structures MA1 to MA4 may be different from each other. There may be no symmetry between the first to fourth sub-meta-structures MA1 to MA4. That is, two adjacent sub-meta-structures (e.g., MA1 and MA2) may be formed in different patterns.

Each of the first to fourth sub-meta-structures MA1 to MA4, as is seen in an enlarged cross-section of a part A1 of the fourth sub-meta-structure MA4, may include a meta pattern 1120 having a first refractive index and being transparent to incident light and a material layer 1130 having a second refractive index different from the first refractive index and being transparent to incident light, but is not limited thereto. A plurality of meta-patterns 1120 may be provided to form a meta-structure, and dimensions (e.g., height, diameter, etc.) of the meta-patterns 1120 may be determined in consideration of the location of the meta-patterns 1120 and the role of the meta-structure. In one example, the second refractive index may be less than the first refractive index.

The meta-pattern 1120 may be a pattern having a size less than a wavelength of incident light, and for example, the meta-pattern 1120 may be a nanostructure having a height and/or a diameter (e.g., a width) less than a wavelength of incident light. In one example, the diameter of the nanostructure may be several nanometers to hundreds of nanometers. In one example, the nanostructure may be a nanopost or may have a similar shape, but is not limited thereto.

Although the first to fourth sub-meta-structures MA1 to MA4 are shown in the form of geometric figures, embodiments are not limited to the planar shape of each of the first to fourth sub-meta-structures MA1 to MA4. In each of the first to fourth sub-meta-structures MA1 to MA4, the meta pattern 1120 is not only located in an area corresponding to a line segment of the figure, but may also be located in an area away from the line segment, and may be distributed in various shapes.

The above descriptions of the first to fourth sub-meta-structures MA1 to MA4 may be equally applied to sub-meta-structures of the second to fifth meta-structures MS2 to MS5 to be described below.

Referring to FIG. 11, the second meta-structure MS2 of the second layer ML2 includes a first sub-meta-structure MB1 corresponding to the first pixel PX1, a second sub-meta-structure MB2 corresponding to the second pixel PX2, a third sub-meta-structure MB3 corresponding to the third pixel PX3, and a fourth sub-meta-structure MB4 corresponding to the fourth pixel PX4 (e.g., pixels PX1-PX4 of FIG. 3), respectively. Each of the first to fourth sub-meta-structures MB1 to MB4 may be formed to be vertically, horizontally, and/or diagonally symmetrical with respect to the center of the corresponding pixel or a reference line (e.g., a horizontal or vertical line) passing through the center. Each of the first to fourth sub-meta-structures MB1 to MB4 may be different from each other, and there may be no symmetry between the first to fourth sub-meta-structures MB1 to MB4. That is, two adjacent sub-meta-structures (e.g., MB1 and MB2) may be formed in different patterns.

Because the second layer ML2 is located on the first layer ML1, the first to fourth sub-meta-structures MB1 to MB4 of the second meta-structure MS2 may be at the locations corresponding to the first to fourth sub-meta-structures MA1 to MA4 of the first meta-structure MS1 on a one-to-one basis.

Comparing FIG. 10 and FIG. 11, the first and second meta-structures MS1 and MS2 are different from each other. In addition, in the meta-structures MS1 and MS2, the first sub-meta-structures MA1 and MB1 are different from each other, the second sub-meta-structures MA2 and MB2 are different from each other, the third sub-meta-structures MA3 and MB3 are also different from each other, and the fourth sub-meta-structures MA4 and MB4 are also different from each other.

Referring to FIG. 12, the third meta-structure MS3 of the third layer ML3 includes a first sub-meta-structure MC1 corresponding to the first pixel PX1, a second sub-meta-structure MC2 corresponding to the second pixel PX3, a third sub-meta-structure MC3 corresponding to the third pixel PX3, and a fourth sub-meta-structure MC4 corresponding to the fourth pixel PX4 (e.g., pixels PX1-PX4 of FIG. 3), respectively. Each of the first to fourth sub-meta-structures MC1 to MC4 may be formed to be vertically, horizontally, and/or diagonally symmetric with respect to the center of a corresponding pixel or a reference line (e.g., a horizontal or vertical line) passing through the center. Each of the first to fourth sub-meta-structures MC1 to MC4 may be different from each other, and there may be no symmetry between the first to fourth sub-meta-structures MC1 to MC4. That is, two adjacent sub-meta-structures (e.g., MC1 and MC2) may be formed in different patterns.

Because the third layer ML3 is located on the second layer ML2, the first to fourth sub-meta-structures MC1 to MC4 of the third meta-structure MS3 may be at locations corresponding to the first to fourth sub-meta-structures MB1 to MB4 of the second meta-structure MS2 on a one-to-one basis.

Comparing FIGS. 10 to 12, the first to third meta-structures MS1 to MS3 are different from each other. In addition, in the meta-structures MS1, MS2, and MS3, the first sub-meta-structures MA1, MB1, and MC1 are different from each other, the second sub-meta-structures MA2, MB2, and MC2 are also different from each other, the third sub-meta-structures MA3, MB3, and MC3 are also different from each other, and the fourth sub-meta-structures MA4, MB4, and MC4 are also different from each other.

Referring to FIG. 13, the fourth meta-structure MS4 of the fourth layer ML4 includes a first sub-meta-structure MD1 corresponding to the first pixel PX1, a second sub-meta-structure MD2 corresponding to the second pixel PX2, a third sub-meta-structure MD3 corresponding to the third pixel PX3, and a fourth sub-meta-structure MD4 corresponding to the fourth pixel PX4 (e.g., pixels PX1-PX4 of FIG. 3), respectively. Each of the first to fourth sub-meta-structures MD1 to MD4 may be formed to be vertically, horizontally, and/or diagonally symmetric with respect to the center of a corresponding pixel or a reference line (e.g., a horizontal or vertical line) passing through the center. Each of the first to fourth sub-meta-structures MD1 to MD4 may be different from each other. There may be no symmetry between the first to fourth sub-meta-structures MD1 to MD4. That is, two adjacent sub-meta-structures (e.g., MD1 and MD2) may be formed in different patterns.

Because the fourth layer ML4 is located on the third layer ML3, the first to fourth sub-meta-structures MD1 to MD4 of the fourth meta-structure MS4 may be at locations corresponding to the first to fourth sub-meta-structures MC1 to MC4 of the third meta-structure MS3 on a one-to-one basis.

Comparing FIGS. 10 to 13, the first to fourth meta-structures MS1 to MS4 are different from each other. In addition, in the meta-structures MS1, MS2, MS3, and MS4, the first sub-meta-structures MA1, MB1, MC1, and MD1 are different from each other, the second sub-meta-structures MA2, MB2, MC2, and MD2 are different from each other, the third sub-meta-structures MA2, MB2, MC2, and MD2 are different from each other, and the fourth sub-meta-structures MA4, MB4, MC4, and MD4 are also different from each other.

Referring to FIG. 14, the fifth meta-structure MS5 of the fifth layer ML5 includes a first sub-meta-structure ME1 corresponding to the first pixel PX1, a second sub-meta-structure ME2 corresponding to the second pixel PX2, a third sub-meta-structure ME3 corresponding to the third pixel PX3, and a fourth sub-meta-structure ME4 corresponding to the fourth pixel PX4 (e.g., pixels PX1-PX4 of FIG. 3), respectively. Each of the first to fourth sub-meta-structures ME1 to ME4 may be formed to be vertically, horizontally, and/or diagonally symmetric with respect to the center of a corresponding pixel or a reference line (e.g., a horizontal or vertical line) passing through the center. Each of the first to fourth sub-meta-structures ME1 to ME4 may be different from each other, and each of the sub-meta-structures ME1 to ME4 may be provided not to have symmetry with each other. That is, two adjacent sub-meta-structures (e.g., ME1 and ME2) may be formed to have different structures.

Because the fifth layer ML5 is located on the fourth layer ML4, the first to fourth sub-meta-structures ME1 to ME4 of the fifth meta-structure MS5 may be at locations corresponding to the first to fourth sub-meta-structures MD1 to MD4 of the fourth meta-structure MS4 on a one-to-one basis.

Comparing FIGS. 10 to 14, the first to fifth meta-structures MS1 to MS5 are different from each other. In addition, in the meta-structures MS1 to MS5, the first sub-meta-structures MA1, MB1, MC1, MD1, and ME1 are different from each other, the second sub-meta-structures MA2, MB2, MC2, MD2, and ME2 are also different from each other, the third sub-meta-structures MA3, MB3, MC3, MD3, and ME3 are also different from each other, and the fourth sub-meta-structures MA4, MB4, MC4, MD4, and ME4 are also different from each other.

As described above, because the meta-structures MS1 to MS5 provided in the first to fifth layers ML1 to ML5 are different from each other, the refractive index in the vertical direction (e.g., a Z-axis direction) of a stack including the first to fifth layers ML1 to ML5 (i.e., a color routing meta-structure layer) may vary, and the color routing meta-structure layer may be a color routing meta-structure layer having a three-dimensional structure including materials having different refractive indices.

In one example, a size of the meta-structures MS1 to MS5 of the first to fifth layers ML1 to ML5 of a color routing meta-structure layer (e.g., 37C) of a pixel, a CRA of which is not 0°, may be maintained constant regardless of the shift of the first to fifth layers ML1 to ML5, but it may not be maintained constant.

In one example, the size of the meta-structures MS1 to MS5 of the first to fifth layers ML1 to ML5 of the color routing meta-structure layer (e.g., 37C) of a pixel located away from the center of an image sensor may be increased or decreased than a size of a meta-structure of the first to fifth layers ML1 to ML5 of a color routing meta-structure layer (e.g., 37A) of a pixel having a CRA of 0°.

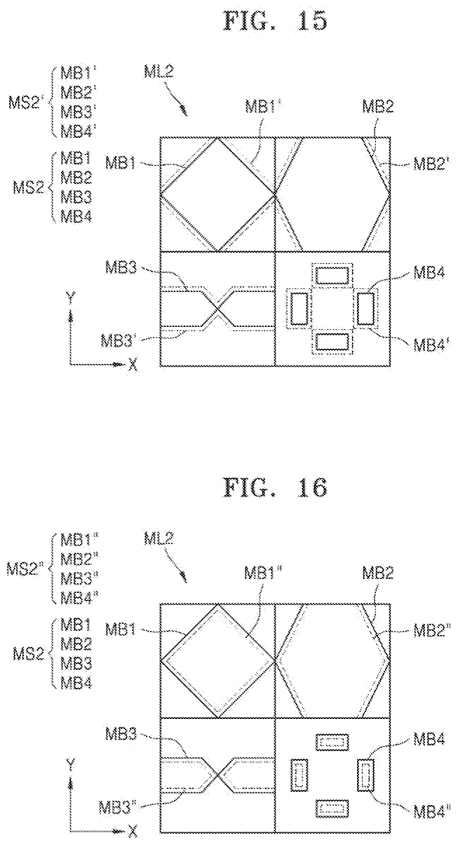

FIG. 15 is a diagram illustrating a case in which a size of a meta-structure of a pixel deviated from the center of an image sensor is increased compared to a size of a meta-structure of a pixel located in the center of an image sensor according to an example embodiment. For example, taking the second layer ML2 as an example, as shown in FIG. 15, sizes of first to fourth sub-meta-structures (dotted lines) MB1′ to MB4′ of a second meta-structure MS2′ of the second layer ML2 of the color routing meta-structure layer (e.g., 37C) of a pixel located away from the center of an image sensor may be greater than the sizes of the first to fourth sub-meta-structures (solid lines) MB1 to MB4 of the second layer MS2 of the color routing meta-structure layer (e.g., 37A) of a pixel having a CRA of 0°. The size of the meta-structure may gradually increase from the center to an edge of an image sensor.

FIG. 16 is a diagram illustrating a case in which a size of a meta-structure of a pixel deviated from the center of an image sensor is reduced compared to a size of a meta-structure of a pixel located in the center of an image sensor according to an example embodiment. That is, FIG. 16 shows a case different from the above case shown in FIG. 15.

Referring to FIG. 16, sizes of first to fourth sub-meta-structures (dotted lines) MB1″ to MB4″ of a second meta-structure MS2″ of the second layer ML2 of the color routing meta-structure layer (e.g., 37C) of pixels located away from the center of an image sensor may be less than the sizes of the first to fourth sub-meta-structures (solid lines) MB1 to MB4 of the second layer ML2 of the color routing meta-structure layer (e.g., 37A) of pixels having a CRA of 0°. The size of the meta-structure may gradually decrease from the center to an edge of an image sensor.

The color routing meta-structure layer shown above may also be applied to an optical device that separates and receives light according to wavelength, polarization, etc., such as a multi-spectral device or a polarization image sensor.

An image sensor including the color routing meta-structure layer according to the embodiment described above may be applied to various electronic devices.

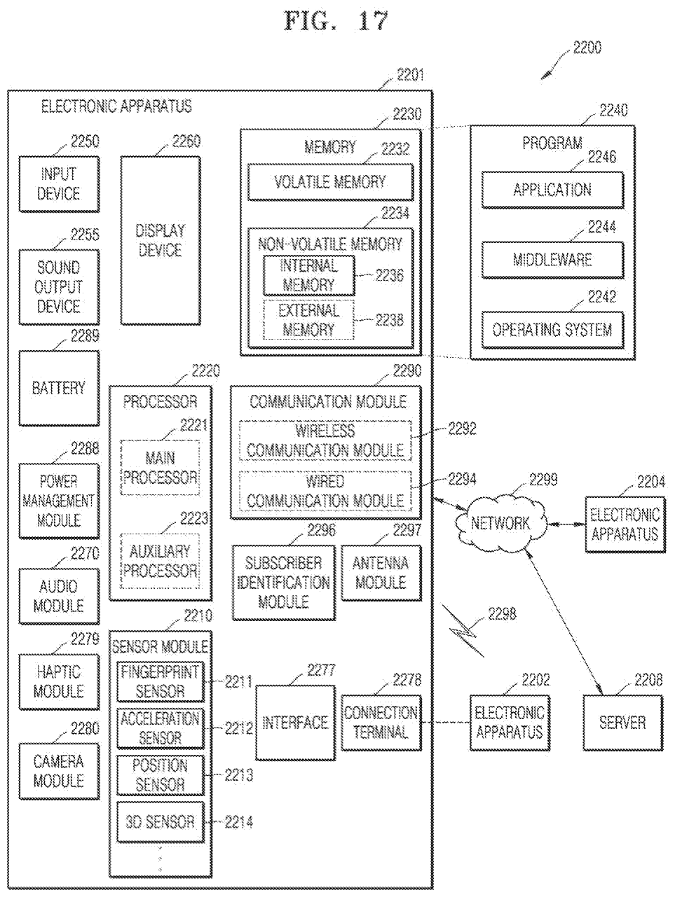

FIG. 17 is a diagram illustrating an electronic device according to an example embodiment. That is, FIG. 17 shows an example of electronic device 2201.

Referring to FIG. 17, as shown in FIG. 17, the electronic device 2201 includes various devices in a network environment 2200.

An electronic apparatus 2201 may communicate with another electronic apparatus 2202 through a first network 2298 (e.g., a short-range wireless communication network, etc.) or may communicate with another electronic apparatus 2204 and/or a server 2208 through a second network 2299 (e.g., a remote wireless communication network). The electronic apparatus 2201 may communicate with the electronic apparatus 2204 through the server 2208. The electronic apparatus 2201 may include a processor 2220, a memory 2230, an input device 2250, an audio output device 2255, a display device 2260, an audio module 2270, a sensor module 2210, an interface 2277, a haptic module 2279, a camera module 2280, a power management module 2288, a battery 2289, a communication module 2290, a subscriber identification module 2296, and/or an antenna module 2297. In the electronic apparatus 2201, some of these components (e.g., the display device 2260) may be omitted or other components may be added. Some of these components may be implemented as one integrated circuit. For example, a fingerprint sensor 2211 of the sensor module 2210, an iris sensor, an illuminance sensor, etc. may be implemented in a form embedded in the display device 2260 (a display, etc.).

The processor 2220 may execute software (such as a program 2240) to control one or a plurality of other components (hardware, software components, etc.) of the electronic apparatus 2201 connected to the processor 2220, and may perform various data processing or operations. As part of data processing or operations, the processor 2220 may load commands and/or data received from other components (the sensor module 2210, the communication module 2290, etc.) into a volatile memory 2232, and may process commands and/or data stored in the volatile memory 2232, and store resulting data in a non-volatile memory 2234. The processor 2220 may include a main processor 2221 (a central processing unit, an application processor, etc.) and an auxiliary processor 2223 (a graphics processing unit, an image signal processor, a sensor hub processor, a communication processor, etc.) that may be operated independently or together with the main processor 2221. The auxiliary processor 2223 may use less power than the main processor 2221 and may perform a specialized function.

The auxiliary processor 2223 may control functions and/or states related to some of the components (e.g., the display device 2260, the sensor module 2210, the communication module 2290) of the electronic apparatus 2201 instead of the main processor 2221 while the main processor 2221 is in an inactive state (sleep state), or together with the main processor 2221 while the main processor 2221 is in an active state (application execution state). The auxiliary processor 2223 (an image signal processor, a communication processor, etc.) may be implemented as a part of other functionally related components (the camera module 2280, the communication module 2290, etc.).

The memory 2230 may store various data required by components of the electronic apparatus 2201 (the processor 2220, the sensor module 2276, etc.). The data may include, for example, input data and/or output data for software (such as the program 2240) and instructions related to the command. The memory 2230 may include a volatile memory 2232 and/or a non-volatile memory 2234. The non-volatile memory 2234 may include an internal memory 2236 and an external memory 2238.

The program 2240 may be stored as software in the memory 2230, and may include an operating system 2242, middleware 2244, and/or an application 2246.

The input device 2250 may receive commands and/or data to be used in a component (e.g., the processor 2220) of the electronic apparatus 2201 from the outside of the electronic apparatus 2201 (e.g., a user). The input device 2250 may include a microphone, a mouse, a keyboard, and/or a digital pen (such as a stylus pen).

The sound output device 2255 may output a sound signal to the outside of the electronic device 2201. The sound output device 2255 may include a speaker and/or a receiver. The speaker may be used for general purposes, such as multimedia playback or recording playback, and the receiver may be used to receive incoming calls. The receiver may be integrated as a part of the speaker or may be implemented as an independent separate device.

The display device 2260 may visually provide information to the outside of the electronic device 2201. The display device 2260 may include a control circuit for controlling a display, a hologram device, or a projector and a corresponding device. The display device 2260 may include a touch circuitry configured to sense a touch, and/or a sensor circuitry configured to measure the intensity of force generated by the touch (e.g., a pressure sensor, etc.).

The audio module 2270 may convert a sound into an electric signal or, conversely, convert an electric signal into a sound. The audio module 2270 may obtain a sound through the input device 2250 or may output a sound through a speaker and/or headphone of the sound output device 2255 and/or another electronic apparatus (e.g., the electronic apparatus 2202) directly or wirelessly connected to electronic apparatus 2201.

The sensor module 2210 may detect an operating state (power, temperature, etc.) of the electronic apparatus 2201 or an external environmental state (user state, etc.), and may generate an electrical signal and/or data value corresponding to the sensed state. The sensor module 2210 may include a fingerprint sensor 2211, an acceleration sensor 2212, a position sensor 2213, a 3D sensor 2214, and the like, and in addition to the above sensors, may include an iris sensor, a gyro sensor, a barometric pressure sensor, a magnetic sensor, a grip sensor, a proximity sensor, a color sensor, an infrared (IR) sensor, a biometric sensor, a temperature sensor, a humidity sensor, and/or an illuminance sensor.

The 3D sensor 2214 may sense a shape and movement of an object by irradiating a desired and/or alternatively predetermined light to the object and analyzing light reflected from the object, and may include a meta-optical device.

The interface 2277 may support one or more designated protocols that may be used by the electronic apparatus 2201 to connect directly or wirelessly with another electronic apparatus (e.g., the electronic device 2102). The interface 2277 may include a High Definition Multimedia Interface (HDMI), a Universal Serial Bus (USB) interface, an SD card interface, and/or an audio interface.

The connection terminal 2278 may include a connector through which the electronic apparatus 2201 may be physically connected to another electronic apparatus (e.g., the electronic apparatus 2202). The connection terminal 2278 may include an HDMI connector, a USB connector, an SD card connector, and/or an audio connector (e.g., a headphone connector).

The haptic module 2279 may convert an electrical signal into a mechanical stimulus (vibration, movement, etc.) or an electrical stimulus that the user may perceive through tactile or kinesthetic sense. The haptic module 2279 may include a motor, a piezoelectric element, and/or an electrical stimulation device.

The camera module 2280 may capture still images and moving images. The camera module 2280 may include a lens assembly including one or more lenses, image sensors, image signal processors, and/or flashes. In one example, the camera module 2280 may include an imaging system including one of the image sensors analogous to FIGS. 1 to 7 and 10 to 16. The lens assembly included in the camera module 2280 may collect light emitted from an object, which is an imaging target.

The power management module 2288 may manage power supplied to the electronic apparatus 2201. The power management module 2288 may be implemented as part of a Power Management Integrated Circuit (PMIC).

The battery 2289 may supply power to components of the electronic device 2201. The battery 2289 may include a non-rechargeable primary cell, a rechargeable secondary cell, and/or a fuel cell.

The communication module 2290 may establish a direct (wired) communication channel and/or a wireless communication channel between the electronic device 2201 and other electronic devices (electronic device 2202, electronic device 2204, server 2208, etc.), and may support a communication performance through the established communication channel. The communication module 2290 may include one or more communication processors that operate independently of the processor 2220 (application processor, etc.) and support direct communication and/or wireless communication. The communication module 2290 may include a wireless communication module 2292 (a cellular communication module, a short-range wireless communication module, a Global Navigation Satellite System (GNSS, etc.) communication module) and/or a wired communication module 2294 (a Local Area Network (LAN) communication module, or a power line communication module, etc.). Among these communication modules, a corresponding communication module may communicate with other electronic devices through a first network 2298 (a short-range communication network, such as Bluetooth, WiFi Direct, or Infrared Data Association (IrDA)) or a second network 2299 (a telecommunication network, such as a cellular network, the Internet, or a computer network (LAN) and WAN, etc.). The various types of communication modules may be integrated into one component (single chip, etc.) or implemented as a plurality of components (plural chips) separate from each other. The wireless communication module 2292 may identify and authenticate the electronic device 2201 within a communication network, such as the first network 2298 and/or the second network 2299 by using subscriber information (such as, International Mobile Subscriber Identifier (IMSI)) stored in a subscriber identification module 2296.

The antenna module 2297 may transmit or receive signals and/or power to and from the outside (other electronic devices, etc.). The antenna may include a radiator having a conductive pattern formed on a substrate (a printed circuit board (PCB), etc.). The antenna module 2297 may include one or a plurality of antennas. When a plurality of antennas is included in the antenna module 2297, an antenna suitable for a communication method used in a communication network, such as the first network 2298 and/or the second network 2299 from among the plurality of antennas may be selected by the communication module 2290. Signals and/or power may be transmitted or received between the communication module 2290 and another electronic device through the selected antenna. In addition to the antenna, other components (an RFIC, etc.) may be included as a part of the antenna module 2297.

Some of the components are connected to each other through a communication method between peripheral devices (a bus, a General Purpose Input and Output (GPIO), a Serial Peripheral Interface (SPI), a Mobile Industry Processor Interface (MIPI), etc.), and may interchange signals (commands, data, etc.).

Commands or data may be transmitted or received between the electronic device 2201 and an external electronic device 2204 through a server 2208 connected to the second network 2299. The other electronic devices 2202 and 2204 may be the same or different types of electronic device 2201. All or some of operations performed in the electronic device 2201 may be performed in one or more of the other electronic devices 2202, 2204, and 2208. For example, when the electronic device 2201 needs to perform a function or service, the electronic device 2201 may request one or more other electronic devices to perform part or all function or service instead of executing the function or service itself. One or more other electronic devices receiving the request may execute an additional function or service related to the request, and transmit a result of the execution to the electronic device 2201. For this purpose, cloud computing, distributed computing, and/or client-server computing technologies may be used.

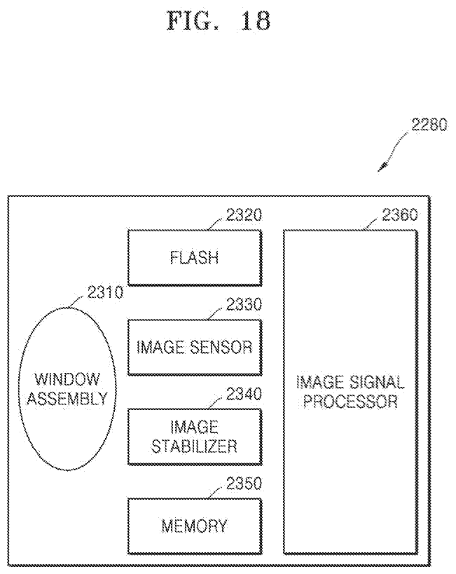

FIG. 18 is a diagram showing a schematic configuration of a camera module included in the electronic device of FIG. 17 according to an example embodiment. That is, FIG. 18 is a block diagram showing a schematic configuration of a camera module 2280 included in the electronic device 2201 of FIG. 17.

Referring to FIG. 18, the camera module 2280 may include a window assembly 2310, a flash 2320, an image sensor 2330, an image stabilizer 2340, a memory 2350 (buffer memory, etc.), and/or an image signal processor 2360. The window assembly 2310 may collect light emitted from an object, which is an image capturing target, and may include a window layer, at least one coded mask layer, a filter layer, and an antireflection film.

The camera module 2280 may include a plurality of window assemblies 2310, and in this case, the camera module 2280 may be a dual camera, a 360° camera, or a spherical camera. Some of the plurality of window assemblies 2310 may have the same lens properties (angle of view, focal length, auto focus, F number, optical zoom, etc.) or different lens properties. The window assembly 2310 may include optical characteristics corresponding to a wide-angle lens or a telephoto lens.

The flash 2320 may emit light used to enhance light emitted or reflected from an object. The flash 2320 may include one or more light-emitting diodes (Red-Green-Blue (RGB) light emitting diode (LED), White LED, Infrared LED, Ultraviolet LED, etc.), and/or a Xenon Lamp. The image sensor 2330 may obtain an image corresponding to an object by converting light emitted or reflected from the object and transmitted through the window assembly 2310 into an electrical signal. The image sensor 2330 may include one of image sensors analogous to the image sensors of FIGS. 1 to 7 and 10 to 16.

The image stabilizer 2340 may move the window assembly 2310 or the image sensor 2330 in a specific direction in response to a movement of the camera module 2280 or an electronic device 2301 including the camera module 2280, or may compensate for negative effects caused by the movement by controlling (adjustment of read-out timing, etc.) the operating characteristics of the image sensor 2330. The image stabilizer 2340 may detect the movement of the camera module 2280 or the electronic device 2301 using a gyro sensor or an acceleration sensor disposed inside or outside the camera module 2280. The image stabilizer 2340 may be optically implemented.

The memory 2350 may store some or all data of an image acquired through the image sensor 2330 for a next image processing work. For example, when a plurality of images are acquired at high speed, the acquired original data (Bayer-patterned data, high-resolution data, etc.) is stored in the memory 2350, only low-resolution images are displayed, and then, the data stored in the memory 2350 may be used so that the original data of the selected (user selection, etc.) image may be transmitted to the image signal processor 2360. The memory 2350 may be integrated into the memory 2230 of the electronic device 2201 or may be configured as a separate memory operated independently. The memory 2350 may also include a restoration algorithm for an image restoration work to be performed by the image signal processor 2360.

The image signal processor 2360 may perform at least one image processing on an image acquired through the image sensor 2330 or image data stored in the memory 2350. The at least one image processing may include depth-map generation, 3D modeling, panorama generation, feature point extraction, image synthesis, image restoration, and/or image compensation (noise reduction, resolution adjustment, brightness adjustment, blurring), sharpening, softening, etc.). The image signal processor 2360 may perform control (exposure time control, read-out timing control, etc.) for elements (the image sensor 2330, etc.) included in the camera module 2280. Images processed by the image signal processor 2360 may be stored again in the memory 2350 for further processing or provided to external components of the camera module 2280 (the memory 2230, the display device 2260, the electronic device 2202, the electronic device 2204, the server 2208, etc.). The image signal processor 2360 may be integrated into the processor 2220 or may be configured as a separate processor that operates independently of the processor 2220. When the image signal processor 2360 is configured as a separate processor from the processor 2220, an image processed by the image signal processor 2360 may be displayed through the display device 2260 after performing an additional image processing by the processor 2220.

The electronic device 2201 may include a plurality of camera modules 2280 each having different properties or functions. In this case, one of the plurality of camera modules 2280 may be a wide-angle camera and the other may be a telephoto camera. Similarly, one of the plurality of camera modules 2280 may be a front camera and the other may be a rear camera.

In the disclosed image sensor, a color routing meta-structure of a pixel located away from a center of an image sensor is shifted toward a center of the image sensor or an optical axis. The degree of shift varies depending on the location of the pixel, and as the CRA increases, that is, as it goes toward an edge of the image sensor, the degree of shift may increase.

In this way, by shifting the color routing meta-structure of a pixel toward a center of an image sensor according to a pixel location or CRA, the decrease in light efficiency (e.g., color separation efficiency) due to the increase in CRA may be minimized or prevented. Accordingly, an image sensor according to the disclosure may provide high-quality images.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An image sensor comprising:
a plurality of pixels, wherein each of the plurality of pixels comprises:
a photoelectric conversion layer; and
a color routing meta-structure layer provided on the photoelectric conversion layer,
wherein a first center line passing through a center of a lower surface and a center of an upper surface of a first color routing meta-structure layer of a first pixel among the plurality of pixels is inclined with respect to a second center line passing through a center of a lower surface and a center of an upper surface of a second color routing meta-structure layer of a second pixel among the plurality of pixels, and
wherein at least one of the first center line and the second center line is inclined with respect to an optical axis of the image sensor.

2. The image sensor of claim 1, wherein each of the plurality of pixels comprises an R pixel, a G pixel, and a B pixel, and
wherein the photoelectric conversion layer comprises four photoelectric conversion elements arranged in a 2×2 array.

3. The image sensor of claim 1, wherein the first pixel and the second pixel are provided at locations away from a center of the image sensor.

4. The image sensor of claim 1, wherein one of the first pixel or the second pixel is provided at a center of the image sensor.

5. The image sensor of claim 1, wherein center lines of color routing meta-structure layers corresponding to the plurality of pixels are inclined differently from each other.

6. The image sensor of claim 1, wherein each of the first color routing meta-structure layer and the second color routing meta-structure layer comprises a plurality of meta-structures, and
wherein each of the plurality of meta-structures is symmetric with respect to a center of a corresponding pixel or a reference line passing through the center of the corresponding pixel.

7. The image sensor of claim 6, wherein the color routing meta-structure layer comprises a plurality of sub-color routing meta-structure layers sequentially provided on the photoelectric conversion layer.

8. The image sensor of claim 7, wherein the plurality of sub-color routing meta-structure layers are shifted toward the optical axis.

9. The image sensor of claim 7, wherein the plurality of sub-color routing meta-structure layers are provided in a layer structure in which a shift increases from a lower layer of the plurality of sub-color routing meta-structure layers to an upper layer of the plurality of sub-color routing meta-structure layers.

10. The image sensor of claim 1, wherein a first size of a first meta-structure of the first color routing meta-structure layer is different from a second size of a second meta-structure of the second color routing meta-structure layer.

11. The image sensor of claim 10, wherein the first size and the second size increase based on a chief ray angle (CRA) of light incident on the first pixel and the second pixel respectively.

12. The image sensor of claim 10, wherein the first size and the second size decrease based on a chief ray angle (CRA) of light incident on the first pixel and the second pixel respectively.

13. The image sensor of claim 10, wherein at least one of the first meta-structure and the second meta-structure comprises a plurality of different sub-meta-structures.

14. The image sensor of claim 1, further comprising a spacer between the photoelectric conversion layer and the color routing meta-structure layer.

15. A meta-optical device comprising:
a plurality of regions respectively corresponding to a plurality of pixels of an image sensor,
wherein the plurality of regions comprises:
a first region comprising a first color routing meta-structure layer, and a second region comprising a second color routing meta-structure layer, and
wherein a first center line passing through a center of a lower surface and a center of an upper surface of the first color routing meta-structure layer is inclined with respect to a second center line passing through a center of a lower surface and a center of an upper surface of the second color routing meta-structure layer.

16. The meta-optical device of claim 15, wherein a first chief ray angle (CRA) of light incident on the first region and a second CRA of light incident on the second region are different.

17. The meta-optical device of claim 15, wherein the first color routing meta-structure layer and the second color routing meta-structure layer comprise layer structures comprising at least one layer shifted towards a center of the image sensor.

18. The meta-optical device of claim 17, wherein the first color routing meta-structure layer comprises a first layer, a second layer, a third layer, a fourth layer, and a fifth layer stacked in sequence and comprising color routing characteristics, and
wherein a first shift of the first layer toward the center of the image sensor is less than at least a second shift of the fifth layer toward the center of the image sensor.

19. The meta-optical device of claim 15, wherein the first color routing meta-structure layer comprises a first meta-structure,
wherein the second color routing meta-structure layer comprises a second meta-structure,
wherein the first meta-structure and the second meta-structure have a same shape, and
wherein the first meta-structure and the second meta-structure have different sizes.

20. An electronic device comprising:
an image sensor, comprising a plurality of pixels,
wherein each of the plurality of pixels comprises:
a photoelectric conversion layer; and
a color routing meta-structure layer provided at a location facing the photoelectric conversion layer,
wherein a first center line passing through a center of a lower surface and a center of an upper surface of a first color routing meta-structure layer of a first pixel of the plurality of pixels is inclined with respect to a second center line passing through a center of a lower surface and a center of an upper surface of a second color routing meta-structure of a second pixel of the plurality of pixels, and
wherein at least one of the first center line and the second center line is inclined with respect to an optical axis of the image sensor.
